(19) United States
(12) Patent Application Publication
(10) Pub. No.: US 2023/0395616 A1
(43) Pub. Date: Dec. 7, 2023

(54) METHOD OF MANUFACTURING ARRAY SUBSTRATE, ARRAY SUBSTRATE, AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Xiaobo Hu, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 17/272,283

(22) PCT Filed: Dec. 30, 2020
(86) PCT No.: PCT/CN2020/141186

§ 371 Date: Aug. 21, 2023

(30) Foreign Application Priority Data
Dec. 28, 2020 (CN) 202011578468.0

(51) Int. Cl. H01L 27/12; H10K 59/124; H10K 59/12

(52) U.S. Cl. CPC H01L 27/1288; H10K 59/124; H10K 59/1201

(57) ABSTRACT

The present disclosure provides a method of manufacturing an array substrate, the array substrate, and a display device. The method of manufacturing the array substrate includes: a step of preparing a substrate; a step of preparing a driving circuit layer on the substrate; a step of preparing a first passivation layer on the driving circuit layer; a step of preparing an original metal layer on the first passivation layer; a step of preparing an oxygen source layer on the original metal layer; a step of heat-treating the oxygen source layer and the original metal layer, wherein the original metal layer is oxidized to form a second passivation layer.

This application claims priority to the patent application filed on Dec. 28, 2020 with the China National Intellectual Property Administration, application number 202011578468.0, titled “method of manufacturing array substrate, array substrate, and display device.” which is incorporated by reference in the present application in its entirety.

### FIELD OF INVENTION

The present application relates to the field of display technology and more particularly to a method of manufacturing an array substrate, the array substrate, and a display device.

### DESCRIPTION OF PRIOR ART

In devices containing thin film transistors (TFTs), in order to protect the thin film transistors from being affected by external water and oxygen, silicon dioxide or silicon nitride will be used to make a passivation layer to isolate external water, oxygen, and other factors in atmosphere. However, silica dioxide is a hydrophilic material that has a poorer ability to isolate water vapor. Silicon nitride has a better ability to isolate water vapor but requires use of silane and ammonia gases in its preparation process, which causes hydrogen content in a prepared silicon nitride film to be too high, and hydrogen element diffuses into a channel layer of the thin film transistors, which will cause deterioration of performance of the thin film transistors. It is also a better choice to use aluminum oxide to make the passivation layer of the thin film transistors. A current method of preparing aluminum oxide film in thin film transistor devices is a method of physically sputtering aluminum oxide targets to form a vapor phase and depositing it; however, because the alumina target is a ceramic target, it is very brittle in nature, and it is difficult to make an alumina target that meets needs of large-size deposition.

Therefore, the current method of preparing the aluminum oxide passivation layer cannot meet requirements for production of the passivation layer of large-size thin film transistor devices.

### SUMMARY OF INVENTION

### Technical Problems

The current method of preparing the aluminum oxide passivation layer cannot meet the requirements for the production of the passivation layer of large-size thin film transistor devices.

### Solutions to Problems

### Technical Solutions

The present application provides a method of manufacturing an array substrate, the array substrate and a display device, which are used for optimizing the process of preparing a metal oxide passivation layer.

The present application provides a method of manufacturing an array substrate, which includes:
a step of providing a substrate;
a step of preparing a driving circuit layer on the substrate;
a step of preparing a first passivation layer on the driving circuit layer;
a step of preparing an original metal layer on the first passivation layer;
a step of preparing an oxygen source layer on the original metal layer;
a step of heat-treating the oxygen source layer and the original metal layer, wherein the original metal layer is oxidized to form a second passivation layer, the oxygen source layer is deoxidized to form a deoxidation layer; and
a step of removing the deoxidation layer.

In the method of manufacturing the array substrate of the present application, the step of preparing the original metal layer on the first passivation layer includes:
depositing the original metal layer of a first thickness on the first passivation layer by a physical deposition process.

In the method of manufacturing the array substrate of the present application, a thickness value of the first thickness ranges from 100 angstroms to 1000 angstroms.

In the method of manufacturing the array substrate of the present application, the step of preparing the oxygen source layer on the original metal layer includes:
depositing the oxygen source layer of a second thickness on the original metal layer by a physical deposition process.

In the manufacturing method of the array substrate of the present application, a thickness value of the second thickness ranges from 500 angstroms to 5000 angstroms.

In the method of manufacturing the array substrate of the present application, the step of heat-treating the oxygen source layer and the original metal layer, wherein the original metal layer is oxidized to form the second passivation layer, and the oxygen source layer is deoxidized to form the deoxidation layer, includes:
performing a heat treatment on the oxygen source layer and the original metal layer over a preset duration at a preset temperature;
the original metal layer is oxidized to form the second passivation layer; and
the oxygen source layer is deoxidized to form the deoxidation layer.

In the method of manufacturing the array substrate of the present application, a temperature value of the preset temperature ranges from 200 degrees centigrade to 500 degrees centigrade, and a time value of the preset duration ranges from 1 minute to 300 minutes.

In the method of manufacturing the array substrate of the present application, after the step of removing the deoxidation layer, the method further includes:
forming a via hole on the first passivation layer and the second passivation layer so that the drain is exposed through the via hole;
forming a pixel electrode layer on the second passivation layer, and wherein the pixel electrode layer is electrically connected to the drain through the via hole.

In the method of manufacturing the array substrate of the present application, a material for preparing the original metal layer includes aluminum.

In the method of manufacturing the array substrate of the present application, a material for preparing the oxygen source layer includes molybdenum oxide and/or indium zinc oxide.

In the method of manufacturing the array substrate of the present application, the step of preparing the driving circuit layer on the substrate includes:
a step of preparing a gate on the substrate;
a step of preparing a gate insulating layer covering the gate;
step of preparing an active layer on the gate insulating layer;
a step of preparing a source and a drain on two opposite ends of the active layer on the gate insulating layer, and wherein the source and the drain are electrically connected to the active layer, respectively.

In the method of manufacturing the array substrate of the present application, the step of preparing the gate on the substrate includes:
depositing a metal conductive layer on the substrate through a physical deposition process;
the metal conductive layer patterned to form the gate through a photomask etching process.

In the method of manufacturing the array substrate of the present application, the step of preparing the source and the drain on two opposite ends of the active layer on the gate insulating layer includes:
depositing the metal conductive layer on the gate insulating layer through a physical deposition process;
patterning the metal conductive layer to form the source and the drain through a photomask etching process.

In the method of manufacturing the array substrate of the present application, the step of preparing the driving circuit layer on the substrate includes:
a step of preparing an active layer on the substrate;
a step of preparing a gate insulating layer on the active layer;
a step of preparing a gate on the gate insulating layer;
a step of preparing an interlayer insulating layer covering the active layer, the gate insulating layer and the gate; and
a step of preparing a source and drain on the interlayer insulating layer, and wherein the source and the drain are electrically connected to two opposite ends of the active layer, respectively.

In the method of manufacturing the array substrate of the present application, the step of preparing the gate on the gate insulating layer includes:
depositing a metal conductive layer on the gate insulating layer through a physical deposition process;
patterning the metal conductive layer to form the gate through a photomask etching process.

In the method of manufacturing the array substrate of the present application, the step of preparing the source and the drain on the interlayer insulating layer includes:
forming a via hole on the interlayer insulating layer by an etching process, and two opposite ends of the active layer are exposed through the via hole;
depositing the metal conductive layer on the interlayer insulating layer by a physical deposition process, and the metal conductive layer is electrically connected to two opposite ends of the active layer through the via hole;
patterning the metal conductive layer to form the source and the drain by a photomask etching process.

In the method of manufacturing the array substrate of the present application, the step of preparing the first passivation layer on the driving circuit layer includes:
preparing a silicon dioxide layer on the driving circuit layer through a chemical vapor deposition process; and
the silicon dioxide layer covers the driving circuit layer to form the first passivation layer.

The present application also provides an array substrate, which is prepared using the method of manufacturing the array substrate as described above.

The present application also provides a display device, which includes the array substrate as described above.

In the display device of the present application, the array substrate comprises a first passivation layer and a second passivation layer disposing on the driving circuit layer, the first passivation layer comprises silicon oxide, and the second passivation layer includes aluminum oxide.

### Beneficial Effect of the Invention

The benefit of the present invention is:

The embodiment of the present application provides a method of manufacturing the array substrate, the method of manufacturing the array substrate includes a step of preparing a driving circuit layer on a substrate, and a step of preparing a passivation layer on the driving circuit layer. Wherein, the step of preparing the passivation layer includes: first, preparing a first passivation layer on the driving circuit layer, and then, preparing an original metal layer and an oxygen source layer are on the first passivation layer, heat-treating the oxygen source layer and the original metal layer, wherein the original metal layer is oxidized to form a second passivation layer, the oxygen source layer is deoxidized to form a deoxidation layer, obtaining the passivation layer covering the driving circuit layer after removing the deoxidizing layer. The method of manufacturing the array substrate is easy to operate and convenient for preparing a large-size metal oxide passivation layer, and the passivation layer formed has a double-layer structure, which improves the ability of the passivation layer to block water and oxygen.

### BRIEF DESCRIPTION OF DRAWINGS OF THE INVENTION

### Description of Drawings

In order to more clearly illustrate the embodiments or the technical solutions of the existing art, the drawings illustrating the embodiments or the existing art will be briefly described below. Obviously, the drawings in the following description merely illustrate some embodiments of the present application. Other drawings may also be obtained by those skilled in the art according to these figures without paying creative work.

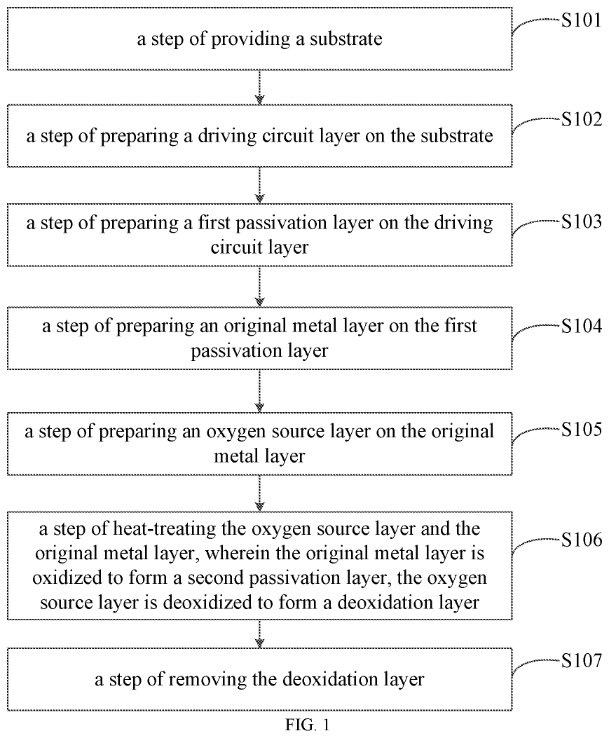

FIG. 1 is a flowchart of a method of manufacturing an array substrate of one embodiment of the present application.

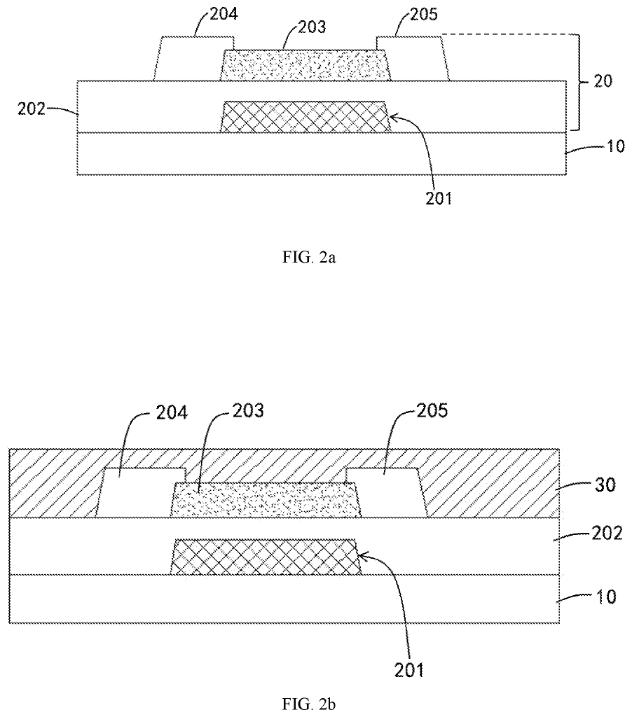

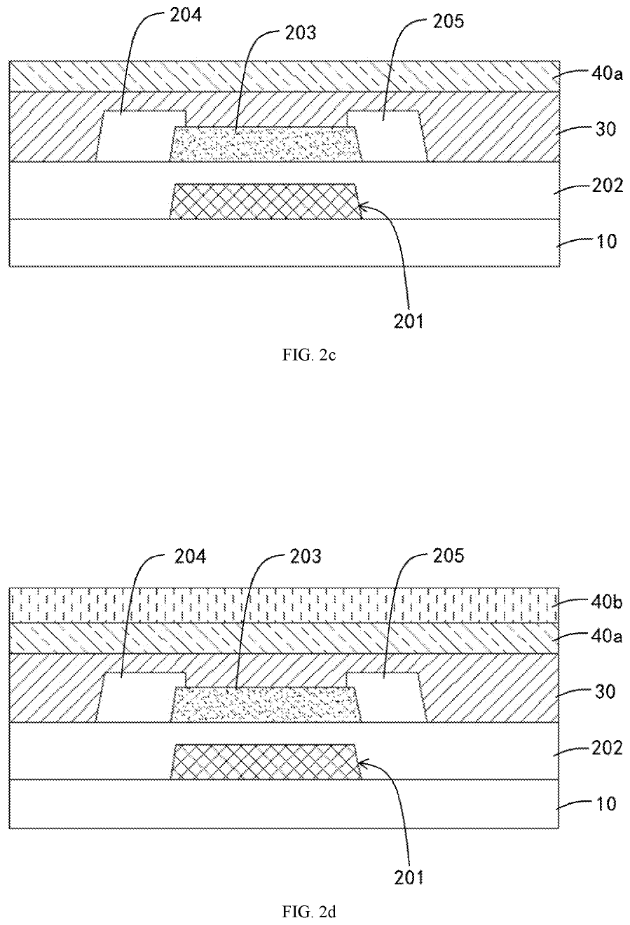

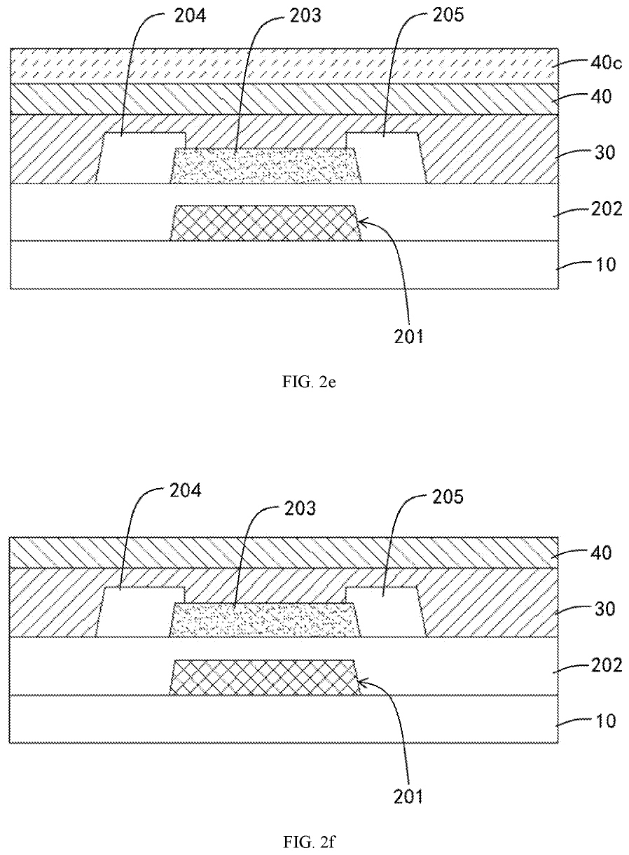

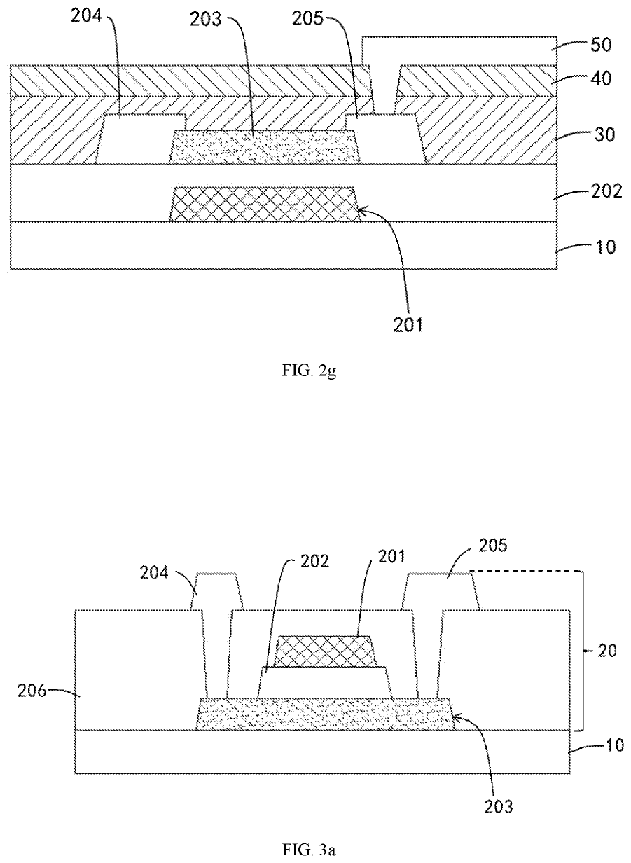

FIG. 2a is a schematic structural diagram of after a driving circuit layer is prepared in a first method of manufacturing the array substrate of one embodiment of the present application.

FIG. 2b is a schematic structural diagram of a first passivation layer is prepared in the first method of manufacturing the array substrate of one embodiment of the present application.

FIG. 2c is a schematic structural diagram of after an original metal layer is prepared in the first method of manufacturing the array substrate of one embodiment of the present application.

FIG. 2d is a schematic structural diagram of after an oxygen source layer is prepared in the first method of manufacturing the array substrate of one embodiment of the present application.

FIG. 2e is a schematic structural diagram of after heat treatment is carried out in the first method of manufacturing the array substrate of one embodiment of the present application.

FIG. 2f is a schematic structural diagram of after a deoxidation layer is removed in the first method of manufacturing the array substrate of one embodiment of the present application.

FIG. 2g is a schematic structural diagram of after a pixel electrode layer is prepared in the first method of manufacturing the array substrate of one embodiment of the present application.

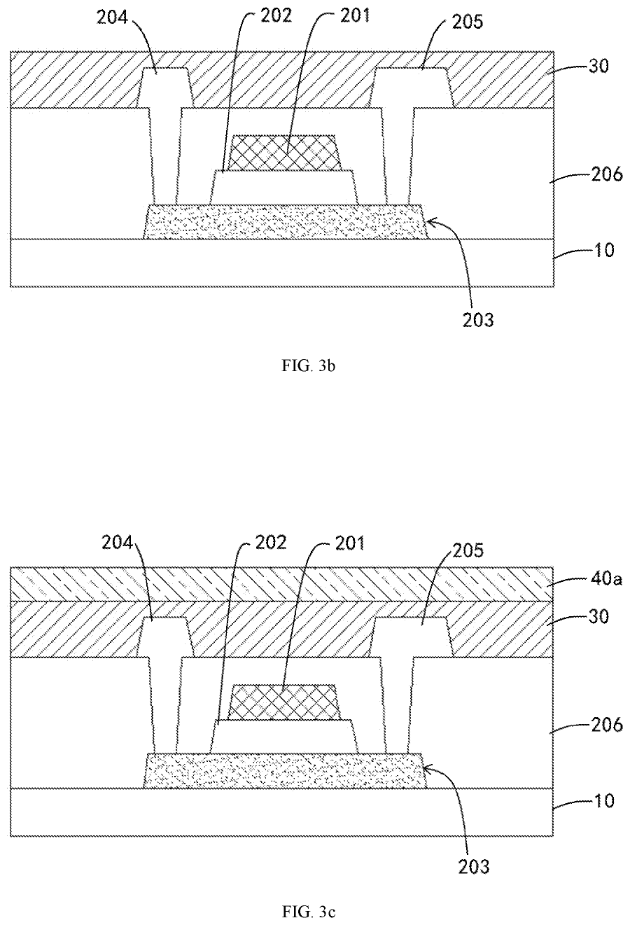

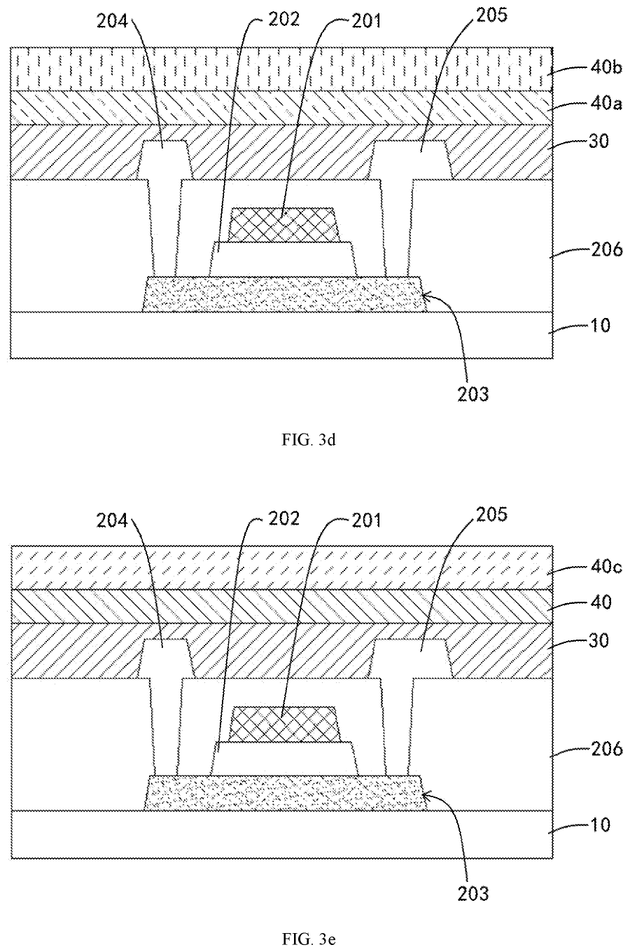

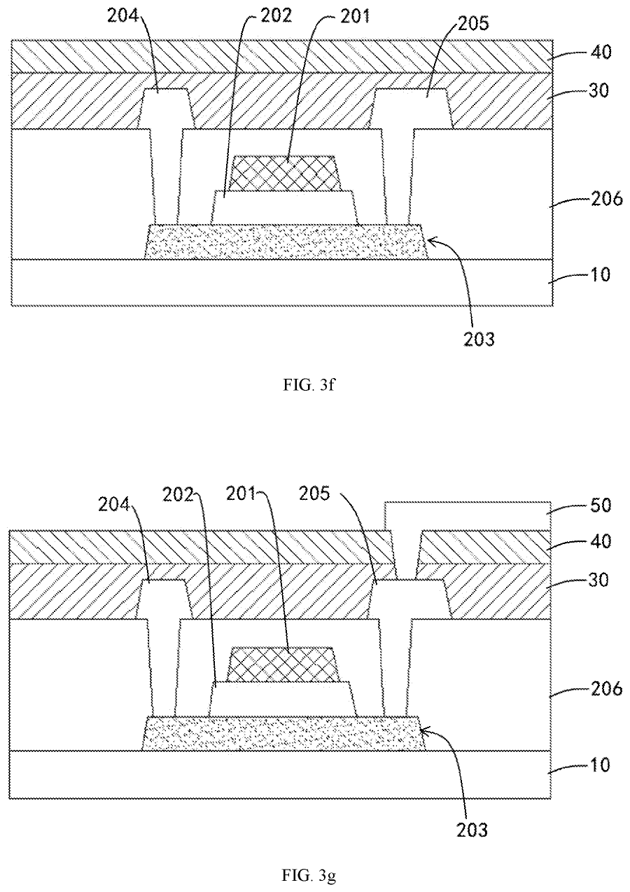

FIG. 3a is a schematic structural diagram of after a driving circuit layer is prepared in a second method of manufacturing the array substrate of one embodiment of the present application.

FIG. 3b is a schematic structural diagram of after a first passivation layer is prepared in the second method of manufacturing the array substrate of one embodiment of the present application.

FIG. 3c is a schematic structural diagram of after an original metal layer is prepared in the second method of manufacturing the array substrate of one embodiment of the present application.

FIG. 3d is a schematic structural diagram of after an oxygen source layer is prepared in the second method of manufacturing the array substrate of one embodiment of the present application.

FIG. 3e is a schematic structural diagram of after heat treatment is carried out in the second method of manufacturing the array substrate of one embodiment of the present application.

FIG. 3f is a schematic structural diagram of after a deoxidation layer is removed in the second method of manufacturing the array substrate of one embodiment of the present application.

FIG. 3g is a schematic structural diagram of after a pixel electrode layer is prepared in the second method of manufacturing the array substrate of one embodiment of the present application.

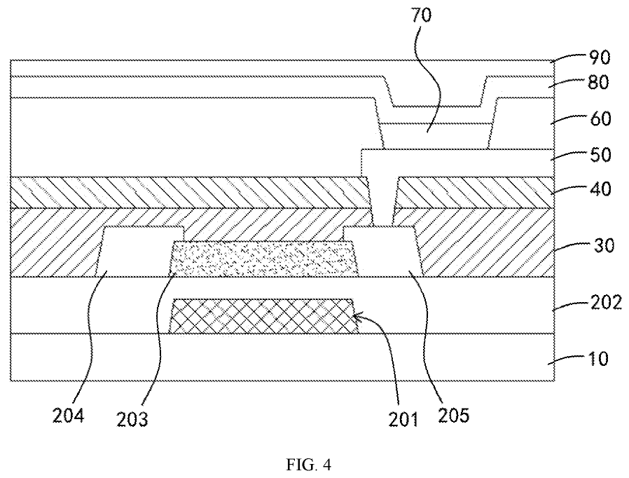

FIG. 4 is a first schematic structural diagram of a display device provided by one embodiment of the present application.

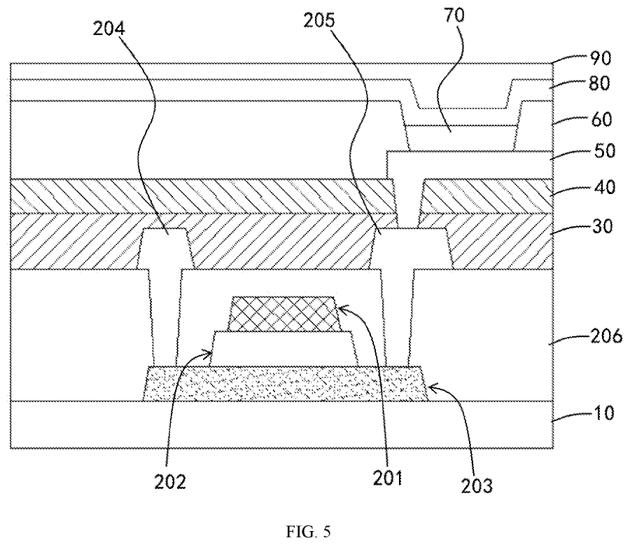

FIG. 5 is a second schematic structural diagram of the display device provided by one embodiment of the present application.

### DETAILED DESCRIPTION OF EMBODIMENTS

### Implementations of the Invention

The following description of the various embodiments is provided to illustrate the specific embodiments of the application. The spatially relative directional terms mentioned in the present application, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references. The spatially relative terms are intended to encompass different orientations in addition to the orientation as depicted in the figures.

An embodiment of the present application provides a method of manufacturing an array substrate, the array substrate, and a display device. The method of manufacturing the array substrate includes a step of preparing a driving circuit layer on a substrate, and a step of preparing a passivation layer on the driving circuit layer. Wherein, the step of preparing the passivation layer includes: first, preparing a first passivation layer on the driving circuit layer, and then, preparing an original metal layer and an oxygen source layer on the first passivation layer, heat-treating the oxygen source layer and the original metal layer, wherein the original metal layer is oxidized to form a second passivation layer, the oxygen source layer is deoxidized to form a deoxidation layer, and the passivation layer covering the driving circuit layer is obtained after removing the deoxidizing layer. The method of manufacturing the array substrate is easy to operate and convenient for preparing a large metal oxide passivation layer, and the passivation layer formed has a double-layer structure, which improves the ability of the passivation layer to block water and oxygen.

Please refer to FIG. 1. FIG. 1 is a flowchart of a method of manufacturing an array substrate of one embodiment of the present application. The array substrate may be a device including a plurality of thin film transistors, and the array substrate can be applied to electronic devices, such as organic light emitting diode display panels and liquid crystal display panels to provide a way to control the electrical functions of these electronic devices. The method of manufacturing the array substrate of one embodiment includes following steps:

Step S101, please refer of FIG. 2a, a step of preparing the substrate 10. The substrate 10 includes an insulating material, for example, the substrate 10 includes one of polyimide, glass, quartz, ceramic, etc. When the final array substrate is applied to a flexible device, the substrate 10 can be made of a flexible material, such as polyimide; when the array substrate is applied to non-flexible devices, the substrate 10 can be made of non-flexible materials, such as glass, quartz, ceramics, etc.

The substrate 10 can remove impurities on the surface through a one-step cleaning operation, the cleaning operation includes: washing the surface of the substrate 10 with pure water, and then removing residual moisture on the surface of the substrate 10 through a drying operation.

Step S102, please refer of FIG. 2a, the step of preparing the driving circuit layer 20 on the substrate 10. The driving circuit layer 20 can include a plurality of thin film transistors to realize current transmission and control.

Further, the step of preparing the driving circuit layer 20 on the substrate 10 includes:

A step of preparing a gate 201 on the substrate 10. A material for preparing the gate 201 includes metal conductive materials such as molybdenum (Mo), copper (Cu), and aluminum (Al). The step of preparing the gate 201 on the substrate 10 includes: first, depositing a metal conductive layer on the substrate 10 through a physical deposition process, wherein, the physical deposition process such as magnetron sputtering. And then, patterning the metal conductive layer to form the gate 201 through a photomask etching process.

A step of preparing a gate insulating layer 202 covering the gate 201 on the substrate 10. A material for preparing the gate insulating layer 202 includes ceramic insulating materials such as silicon nitride and silicon oxide. the step of preparing the gate insulating layer 202 includes: depositing a silicon nitride ceramic layer covering the gate 201 on the substrate 10 using silane (SiH₄) and ammonia gas (NH₃) to form the gate insulating layer 202 by a chemical vapor deposition process; or depositing a silicon nitride ceramic layer covering the gate 201 on the substrate 10 using silane (SiH₄) and nitrous oxide (N₂O) to form the gate insulating layer 202 by the chemical vapor deposition process.

A step of preparing an active layer 203 on the gate insulating layer 202. A material for preparing the active layer 203 includes semiconductor metal oxides such as indium gallium zinc oxide (IGZO), indium gallium zinc tin oxide (IGZTO), and indium gallium tin oxide (IGTO). The step of preparing the active layer 203 includes: depositing a metal oxide semiconductor layer on the gate insulating layer 202 through the chemical vapor deposition process; then, forming a source region, a drain region, and a channel region on the metal oxide semiconductor layer by an ion doping process.

A step of preparing a source 204 and a drain 205 on two opposite ends of the active layer 203 on the gate insulating layer 202, wherein the source 204 and the drain 205 are electrically connected to the active layer 203, respectively. Materials for preparing the source 204 and the drain 205 include molybdenum (Mo), copper (Cu), aluminum (Al), and other metal conductive materials. The step of preparing the source 204 and the drain 205 includes: depositing the metal conductive layer on the gate insulating layer 202 through a physical deposition process, wherein the physical deposition process includes magnetron sputtering, and patterning the metal conductive layer to form the source 204 and the drain 205 through a photomask etching process. The source 204 is arranged corresponding to the source region of the active layer 203 and maintains electrical connection; the drain 205 is arranged corresponding to the drain region of the active layer 203 and maintains electrical connection.

It should be noted that, in this embodiment, the gate 201, the gate insulating layer 202, the active layer 203, the source 204, and the drain 205 constitute a bottom-gate thin film transistor.

Step S103, please refer to FIG. 2a and FIG. 2b, a step of preparing the first passivation layer 30 on the driving circuit layer 20.

Optionally, the material for preparing the first passivation layer 30 includes silicon dioxide. The first passivation layer 30 covers the driving circuit layer 20; specifically, the first passivation layer 30 covers the active layer 203, the source 204, and the drain 205. The first passivation layer 30 prevents external water and oxygen from corroding the active layer 203 and serves as an insulating layer for the active layer 203, the source 204, and the drain 205.

Further, the step of preparing the first passivation layer 30 on the driving circuit layer 20 includes: depositing a silicon dioxide layer on the driving circuit layer 20 using the chemical vapor deposition process, using silane (SiH₄) and nitrous oxide (N₂O) as reaction gases. The silicon dioxide layer covers the driving circuit layer 20 and specifically covers the active layer 203, the source 204, and the drain 205 to form the first passivation layer 30. A thickness of the first passivation layer 30 can be adjusted by controlling a duration of the chemical vapor deposition. In applications, the thickness of the first passivation layer 30 prepared can be freely selected according to actual requirements.

Step S104, please refer of FIG. 2c, a step of preparing the original metal layer 40a on the first passivation layer 30.

Optionally, a material for preparing the original metal layer 40a includes aluminum. The step of preparing the original metal layer 40a on the first passivation layer 30 includes: depositing the original metal layer 40a of a first thickness on the first passivation layer 30 by a physical deposition process, wherein the physical deposition process such as magnetron sputtering, a thickness value of the first thickness ranges from 100 angstroms to 1000 angstroms. Optionally, the target material for preparing the original metal layer 40a by the physical deposition process is a metal aluminum target.

It should be noted that the original metal layer 40a experiences an oxidation reaction under certain heat treatment conditions to generate a metal oxide with a good ability to isolate water and oxygen. Therefore, the material for preparing the original metal layer 40a is not limited to aluminum, and can also be other metal materials that can achieve the same effect.

Step S105, please refer of FIG. 2d, a step of preparing the oxygen source layer 40b on the original metal layer 40a.

Optionally, a material for preparing the oxygen source layer 40b includes unstable amorphous oxide materials such as molybdenum oxide and indium zinc oxide.

A step of preparing the oxygen source layer 40b on the original metal layer 40a includes: depositing the oxygen source layer 40b of a second thickness on the original metal layer 40a by a physical deposition process, wherein the physical deposition process such as magnetron sputtering, a thickness value of the second thickness ranges from 500 angstroms to 5000 angstroms. Optionally, a target material for preparing the oxygen source layer 40b by the physical deposition process may be a molybdenum oxide target material or an indium zinc oxide target material.

It should be noted that the oxygen source layer 40b experiences a reduction reaction under certain heat treatment conditions, and provides oxygen to the original metal layer 40a, so that the original metal layer 40a generates a metal oxide. Therefore, the material for preparing the oxygen source layer 40b is not limited to molybdenum oxide or indium zinc oxide, and can also be other materials that can achieve the same effect.

Step S106, please refer of FIG. 2d and FIG. 2e, a step of heat-treating the oxygen source layer 40b and the original metal layer 40a, wherein the original metal layer 40a is oxidized to form the second passivation layer 40, and the oxygen source layer 40b is deoxidized to form the deoxidation layer 40c.

Specifically, the step of heat-treating the oxygen source layer 40b and the original metal layer 40a includes: performing heat treatment on the oxygen source layer 40b and the original metal layer 40a at a preset temperature, and keeping the oxygen source layer 40b and the original metal layer 40a at the preset temperature for a preset period of time. The original metal layer 40a is oxidized to form the second passivation layer 40, and the oxygen source layer 40b is deoxidized to form the deoxidation layer 40c. Optionally, a temperature value of the preset temperature ranges from 200 degrees centigrade to 500 degrees centigrade, and a time value of the preset duration ranges from 1 minute to 300 minutes. It should be noted that, for the original metal layer 40a with different thicknesses, during the heat treatment, the original metal layer 40a can be completely oxidized by adjusting the heat treatment temperature and/or the duration of heat treatment to form the second passivation layer 40.

Optionally, the material for preparing the second passivation layer 40 after the heat treatment may be aluminum oxide, and a material for preparing the deoxidation layer 40c may be deoxidized molybdenum oxide or deoxidized indium zinc oxide. For example, when the material of the oxygen source layer 40b is the first molybdenum oxide (MoOx), and the material of the deoxidizing layer 40c formed after the heat treatment is the second molybdenum oxide (MoOy), then x>y.

It should be noted that, in this embodiment, the second passivation layer 40 is provided using the method of the heat treatment and the oxidation. This method can realize the production of an aluminum oxide passivation layer for large-size array substrates and meets the current manufacturing requirements of large-size thin film transistor devices. And the double-layer passivation layer structure of the first passivation layer 30 and the second passivation layer 40 greatly improves the ability of the passivation layer to isolate water and oxygen.

Step S107, please refer of FIG. 2e and FIG. 2f, a step of removing the deoxidation layer 40c to form the array substrate structure shown in FIG. 2f.

Optionally, please refer of FIG. 2g, after the step of removing the deoxidation layer 40c, the method of manufacturing the array substrate further includes: forming a via hole on the first passivation layer 30 and the second passivation layer 40, so that the drain 205 is exposed through the via hole; forming a pixel electrode layer 50 on the second passivation layer 40, and wherein the pixel electrode layer 50 is electrically connected to the drain 205 through the via hole.

The pixel electrode layer 50 may be an indium tin oxide electrode. A step of forming the pixel electrode layer 50 includes: depositing an indium tin oxide layer on the second passivation layer 40 through a chemical vapor deposition process, wherein the indium tin oxide layer is electrically connected to the drain 205 through the via hole, and patterning the indium tin oxide layer to form the pixel electrode layer 50.

In an embodiment, the method of manufacturing the array substrate may further include following steps:

Step S101, please refer of FIG. 3a, a step of providing the substrate 10. The substrate 10 includes an insulating material, for example, the substrate 10 includes one of polyimide, glass, quartz, ceramic, etc. When the final array substrate is applied to a flexible device, the substrate 10 can be made of a flexible material, such as polyimide; when the array substrate is applied to non-flexible devices, the substrate 10 can be made of non-flexible materials, such as glass, quartz, ceramics, etc.

The substrate 10 can remove impurities on the surface through a one-step cleaning operation, the cleaning operation includes: washing the surface of the substrate 10 with pure water, and then removing residual moisture on the surface of the substrate 10 through a drying operation.

Step S102, please refer of FIG. 3a, the step of preparing the driving circuit layer 20 on the substrate 10. The driving circuit layer 20 can include a plurality of thin film transistors to realize current transmission and control.

Further, the step of preparing the driving circuit layer 20 on the substrate 10 includes:

A step of preparing the active layer 203 on the substrate 10. The material for preparing the active layer 203 includes semiconductor metal oxides such as indium gallium zinc oxide (IGZO), indium gallium zinc tin oxide (IGZTO), and indium gallium tin oxide (IGTO). The step of preparing the active layer 203 includes: depositing a metal oxide semiconductor layer on the substrate 10 through the chemical vapor deposition process; then, forming a source region, a drain region, and a channel region on the metal oxide semiconductor layer by an ion doping process.

A step of preparing the gate insulating layer 202 on the active layer 203. The material for preparing the gate insulating layer 202 includes ceramic insulating materials such as silicon nitride and silicon oxide. The step of preparing the gate insulating layer 202 includes: depositing a silicon nitride ceramic layer on the active layer 203 using silane (SiH₄) and ammonia gas (NH₃) to form the gate insulating layer 202 by the chemical vapor deposition process; or depositing a silicon nitride ceramic layer on the active layer 203 using silane (SiH₄) and nitrous oxide (N₂O) to form the gate insulating layer 202 by the chemical vapor deposition process.

A step of preparing a gate 201 on the gate insulating layer 202. A material for preparing the gate 201 includes metal conductive materials such as molybdenum (Mo), copper (Cu), and aluminum (Al). The step of preparing the gate 201 includes: first, depositing a metal conductive layer on the gate insulating layer 202 through a physical deposition process such as magnetron sputtering, and then, patterning the metal conductive layer to form the gate 201 through a photomask etching process.

A step of preparing an interlayer insulating layer 206 covering the active layer 203, the gate insulating layer 202, and the gate 201. A material for preparing the interlayer insulating layer 206 includes silicon nitride, silicon oxide, etc. The method of preparing the interlayer insulating layer 206 can be chemical vapor deposition.

A step of preparing the source 204 and the drain 205 on the interlayer insulating layer 206, wherein the source 204 and the drain 205 are electrically connected to two opposite ends of the active layer, respectively. A material for preparing the source 204 and the drain 205 includes metal conductive materials such as molybdenum (Mo), copper (Cu), and aluminum (Al). The step of preparing the source 204 and the drain 205 includes: forming a via hole on the interlayer insulating layer 206 by an etching process, and two opposite ends of the active layer 203 are exposed through the via hole; depositing the metal conductive layer on the interlayer insulating layer 206 by a physical deposition process, and the metal conductive layer is electrically connected to two opposite ends of the active layer 203 through the via hole, wherein, the physical deposition process includes magnetron sputtering; and patterning the metal conductive layer to form the source 204 and the drain 205 by a photomask etching process. The source 204 is arranged corresponding to the source region of the active layer 203 and maintains electrical connection; and the drain 205 is arranged corresponding to the drain region of the active layer 203 and maintains electrical connection.

It should be noted that, in this embodiment, the gate 201, the gate insulating layer 202, the active layer 203, the source 204, and the drain 205 constitute a top-gate thin film transistor.

Step S103, please refer of FIG. 2a and FIG. 2b, a step of preparing the first passivation layer 30 on the driving circuit layer 20.

Optionally, a material for preparing the first passivation layer 30 includes silicon dioxide. The first passivation layer 30 covers the driving circuit layer 20; specifically, the first passivation layer 30 covers the active layer 203, the source 204, and the drain 205. The first passivation layer 30 is prevents external water and oxygen from corroding the active layer 203 and serves as an insulating layer for the active layer 203, the source 204, and the drain 205.

Further, the step of preparing the first passivation layer 30 on the driving circuit layer 20 includes: depositing a silicon dioxide layer on the driving circuit layer 20 using the chemical vapor deposition process, using silane (SiH₄) and nitrous oxide (N₂O) as reaction gases. The silicon dioxide layer covers the driving circuit layer 20, specifically, which covers the active layer 203, the source 204, and the drain 205 to form the first passivation layer 30. A thickness of the first passivation layer 30 can be adjusted by controlling the duration of the chemical vapor deposition. In applications, the thickness of the first passivation layer 30 prepared can be freely selected according to actual requirements.

Step S104, please refer of FIG. 3c, a step of preparing the original metal layer 40a on the first passivation layer 30.

Optionally, a material for preparing the original metal layer 40a includes aluminum. The step of preparing the original metal layer 40a on the first passivation layer 30 includes: depositing the original metal layer 40a of a first thickness on the first passivation layer 30 by a physical deposition process, wherein the physical deposition process such as magnetron sputtering, a thickness value of the first thickness ranges from 100 angstroms to 1000 angstroms. Optionally, the target material for preparing the original metal layer 40a by the physical deposition process is a metal aluminum target.

It should be noted that the original metal layer 40a experiences an oxidation reaction under certain heat treatment conditions to generate a metal oxide with a good ability to isolate water and oxygen. Therefore, the material for preparing the original metal layer 40a is not limited to aluminum, and can also be other metal materials that can achieve the same effect.

Step S105, please refer of FIG. 3d, a step of preparing the oxygen source layer 40b on the original metal layer 40a.

Optionally, the material for preparing the oxygen source layer 40b includes unstable amorphous oxide materials such as molybdenum oxide and indium zinc oxide.

A step of preparing the oxygen source layer 40b on the original metal layer 40a includes: depositing the oxygen source layer 40b of a second thickness on the original metal layer 40a by the physical deposition process, such as magnetron sputtering, and a thickness value of the second thickness ranges from 500 angstroms to 5000 angstroms. Optionally, the target material for preparing the oxygen source layer 40b by the physical deposition process may be a molybdenum oxide target material or an indium zinc oxide target material.

It should be noted that the oxygen source layer 40b experiences a reduction reaction under certain heat treatment conditions and provides oxygen to the original metal layer 40a, so that the original metal layer 40a generates a metal oxide. Therefore, the material for preparing the oxygen source layer 40b is not limited to molybdenum oxide or indium zinc oxide, and can also be other materials that can achieve the same effect.

Step S106, please refer of FIG. 3d and FIG. 3e, a step of heat-treating the oxygen source layer 40b and the original metal layer 40a, wherein the original metal layer 40a is oxidized to form the second passivation layer 40, the oxygen source layer 40b is deoxidized to form the deoxidation layer 40c.

Specifically, the step of heat-treating the oxygen source layer 40b and the original metal layer 40a includes: performing heat treatment on the oxygen source layer 40b and the original metal layer 40a over a preset duration at a preset temperature and keeping the oxygen source layer 40b and the original metal layer 40a at the preset temperature for a preset period of time; the original metal layer 40a is oxidized to form the second passivation layer 40, and the oxygen source layer 40b is deoxidized to form the deoxidation layer 40c. Optionally, a temperature value of the preset temperature ranges from 200 degrees centigrade to 500 degrees centigrade, and a time value of the preset duration ranges from 1 minute to 300 minutes. It should be noted that, for the original metal layer 40a with different thicknesses, during the heat treatment, the original metal layer 40a can be completely oxidized by adjusting the heat treatment temperature and/or heat treatment time to form the second passivation layer 40.

Optionally, the material for preparing a second passivation layer 40 after the heat treatment may be aluminum oxide, and the material for preparing the deoxidation layer 40c may be deoxidized molybdenum oxide or deoxidized indium zinc oxide. For example, when the material of the oxygen source layer 40b is the first molybdenum oxide (MoOx), and the material of the deoxidizing layer 40c formed after the heat treatment is the second molybdenum oxide (MoOy), then x>y.

It should be noted that, in this embodiment, the second passivation layer 40 is provided using the method of heat treatment and oxidation. This method can realize the production of an aluminum oxide passivation layer for large-size array substrates, meet the current manufacturing requirements of large-size thin film transistor devices, and form the double-layer passivation layer structure of the first passivation layer 30 and the second passivation layer 40 which greatly improves the ability of the passivation layer to isolate water and oxygen.

Step S107, please refer of FIG. 3e and FIG. 3f, a step of removing the deoxidation layer 40c to form the array substrate structure shown in FIG. 3f.

Optionally, please refer of FIG. 3g, after the step of removing the deoxidation layer 40c, the method of manufacturing the array substrate further includes: forming a via hole on the first passivation layer 30 and the second passivation layer 40, so that the drain 205 is exposed through the via hole; forming a pixel electrode layer 50 on the second passivation layer 40, wherein the pixel electrode layer 50 is electrically connected to the drain 205 through the via hole.

The pixel electrode layer 50 may be an indium tin oxide electrode. A step of forming the pixel electrode layer 50 includes: depositing an indium tin oxide layer on the second passivation layer 40 through a chemical vapor deposition process, and the indium tin oxide layer is electrically connected to the drain 205 through the via hole; patterning the indium tin oxide layer to form the pixel electrode layer 50.

In summary, the embodiments of the present application provide a method of manufacturing an array substrate, the method of manufacturing the array substrate includes a step of preparing a driving circuit layer on a substrate, and a step of preparing a passivation layer on the driving circuit layer. Wherein, the step of preparing the passivation layer includes: first, preparing a first passivation layer on the driving circuit layer, and then, preparing an original metal layer and an oxygen source layer are on the first passivation layer; heat-treating the oxygen source layer and the original metal layer, wherein the original metal layer is oxidized to form a second passivation layer; the oxygen source layer is deoxidized to form a deoxidation layer; and obtaining the passivation layer covering the driving circuit layer after removing the deoxidizing layer. The method of manufacturing the array substrate is easy to operate and convenient for preparing a large-size metal oxide passivation layer, and the passivation layer formed has a double-layer structure, which improves the ability of the passivation layer to block water and oxygen.

An embodiment of the present application also provides the array substrate, which is provided using the method of preparing the array substrate described in the foregoing embodiments. The array substrate has a structure same as or similar to the array substrate shown in FIG. 2g, or has a structure same or similar to the array substrate shown in FIG. 3g.

An embodiment of the present application also provides a display device, which includes the array substrate provided in the embodiments of the present application, or the array substrate prepared using the method of manufacturing the array substrate provided in the embodiments of the present application. The display device may be an organic light-emitting diode display device or a liquid crystal display device.

In an embodiment, the display device has a structure as shown in FIG. 4. The display device includes the array substrate provided in the embodiments of the present application. The array substrate includes a substrate 10, a gate 201 disposed on the substrate 10, a gate insulating layer 202 covering the gate 201, an active layer 203 disposed on the gate insulating layer 202, a source 204 and a drain 205 disposed at two opposite ends of the active layer 203, a first passivation layer 30 covering the active layer 203, the source 204, and the drain 205, a second passivation layer 40 disposed on the first passivation layer 30, and a pixel electrode layer 50 disposed on the second passivation layer 40 and electrically connected to the drain 205.

Further, the display device includes a light-emitting layer disposed on the array substrate, the light emitting layer uses the pixel electrode layer 50 as an anode, and the light-emitting layer includes a pixel definition layer 60 disposed on the pixel electrode layer 50, an organic functional layer 70 disposed in the opening of the pixel definition layer 60, a cathode 80 disposed on the pixel definition layer 60, and a thin film encapsulation layer 90 disposed on the cathode 80. The pixel electrode layer 50, the organic functional layer 70, and the cathode 80 are electrically connected in sequence at the opening corresponding to the pixel definition layer 60.

In an embodiment, the display device has a structure as shown in FIG. 5. The display device includes the array substrate provided in the embodiments of the present application. The array substrate includes a substrate 10, an active layer 203 disposed on the substrate 10, a gate insulating layer 202 disposed on the active layer 203, a gate 201 disposed on the gate insulating layer 202, an interlayer insulating layer 206 covering the active layer 203, the gate insulating layer 202, and the gate 201, a source 204 and a drain 205, which are disposed on the interlayer insulating layer 206 and electrically connected to two opposite ends of the active layer 203, a first passivation layer 30 covering the source 204 and the drain 205, a second passivation layer 40 disposed on the first passivation layer 30, and a pixel electrode layer 50 disposed on the second passivation layer 40 and electrically connected to the drain 205.

Further, the display device includes a light-emitting layer disposed on the array substrate, the light emitting layer uses the pixel electrode layer 50 as an anode, and the light emitting layer includes a pixel definition layer 60 disposed on the pixel electrode layer 50, an organic functional layer 70 disposed in the opening of the pixel definition layer 60, a cathode 80 disposed on the pixel definition layer 60, and a thin film encapsulation layer 90 disposed on the cathode 80. The pixel electrode layer 50, the organic functional layer 70, and the cathode 80 are electrically connected in sequence at the opening corresponding to the pixel definition layer 60.

In summary, although the present application has been disclosed in preferred embodiments as above, the above-mentioned preferred embodiments are not intended to limit the present application. Those of ordinary skill in the art can make various modifications without departing from the spirit and scope of the present application. Such changes and modifications, therefore, the protection scope of the present application is subject to the scope defined by the claims.

1. A method of manufacturing an array substrate, comprising:
a step of providing a substrate;
a step of preparing a driving circuit layer on the substrate;
a step of preparing a first passivation layer on the driving circuit layer;
a step of preparing an original metal layer on the first passivation layer;
a step of preparing an oxygen source layer on the original metal layer;
a step of heat-treating the oxygen source layer and the original metal layer, wherein the original metal layer is oxidized to form a second passivation layer, and the oxygen source layer is deoxidized to form a deoxidation layer; and
a step of removing the deoxidation layer.

2. The method of manufacturing the array substrate according to claim 1, wherein the step of preparing the original metal layer on the first passivation layer includes:
depositing the original metal layer of a first thickness on the first passivation layer by a physical deposition process.

3. The method of manufacturing the array substrate according to claim 2, wherein a thickness value of the first thickness ranges from 100 angstroms to 1000 angstroms.

4. The method of manufacturing the array substrate according to claim 1, wherein the step of preparing the oxygen source layer on the original metal layer includes:
depositing the oxygen source layer of a second thickness on the original metal layer by a physical deposition process.

5. The method of manufacturing the array substrate according to claim 4, wherein a thickness value of the second thickness ranges from 500 angstroms to 5000 angstroms.

6. The method of manufacturing the array substrate according to claim 1, wherein the step of heat-treating the oxygen source layer and the original metal layer, wherein the original metal layer is oxidized to form the second passivation layer, and the oxygen source layer is deoxidized to form the deoxidation layer, includes:
performing heat treatment on the oxygen source layer and the original metal layer over a preset duration at a preset temperature;
the original metal layer is oxidized to form the second passivation layer; and
the oxygen source layer is deoxidized to form the deoxidation layer.

7. The method of manufacturing the array substrate according to claim 6, wherein a temperature value of the preset temperature ranges from 200 degrees centigrade to 500 degrees centigrade, and a time value of the preset duration ranges from 1 minute to 300 minutes.

8. The method of manufacturing the array substrate according to claim 1, wherein after the step of removing the deoxidation layer, the method further includes:
forming a via hole on the first passivation layer and the second passivation layer, so that drain is exposed through the via hole; and
forming a pixel electrode layer on the second passivation layer, wherein the pixel electrode layer is electrically connected to the drain through the via hole.

9. The method of manufacturing the array substrate according to claim 1, wherein a material for preparing the original metal layer includes aluminum.

10. The method of manufacturing the array substrate according to claim 1, wherein a material for preparing the oxygen source layer includes molybdenum oxide and/or indium zinc oxide.

11. The method of manufacturing the array substrate according to claim 1, wherein the step of preparing the driving circuit layer on the substrate includes:
a step of preparing a gate on the substrate;
a step of preparing a gate insulating layer covering the gate;
a step of preparing an active layer on the gate insulating layer; and
a step of preparing a source and a drain on two opposite ends of the active layer on the gate insulating layer, wherein the source and the drain are electrically connected to the active layer, respectively.

12. The method of manufacturing the array substrate according to claim 11, wherein the step of preparing the gate on the substrate includes:
depositing a metal conductive layer on the substrate through a physical deposition process; and
patterning the metal conductive layer to form the gate through a photomask etching process.

13. The method of manufacturing the array substrate according to claim 11, wherein the step of preparing the source and the drain on the two opposite ends of the active layer on the gate insulating layer includes:
depositing a metal conductive layer on the gate insulating layer through a physical deposition process; and
patterning the metal conductive layer to form the source and the drain through a photomask etching process.

14. The method of manufacturing the array substrate according to claim 1, wherein the step of preparing the driving circuit layer on the substrate includes:
a step of preparing an active layer on the substrate;
a step of preparing a gate insulating layer on the active layer;
a step of preparing a gate on the gate insulating layer;
a step of preparing an interlayer insulating layer covering the active layer, the gate insulating layer, and the gate; and
a step of preparing a source and a drain on the interlayer insulating layer, wherein the source and the drain are electrically connected to two opposite ends of the active layer, respectively.

15. The method of manufacturing the array substrate according to claim 14, wherein the step of preparing the gate on the gate insulating layer includes:
depositing a metal conductive layer on the gate insulating layer through a physical deposition process; and
patterning the metal conductive layer to form the gate through a photomask etching process.

16. The method of manufacturing the array substrate according to claim 14, wherein the step of preparing the source and the drain on the interlayer insulating layer includes:
forming a via hole on the interlayer insulating layer by an etching process, and the two opposite ends of the active layer are exposed through the via hole;
depositing a metal conductive layer on the interlayer insulating layer by a physical deposition process, and the metal conductive layer is electrically connected to the two opposite ends of the active layer through the via hole; and
patterning the metal conductive layer to form the source and the drain by a photomask etching process.

17. The method of manufacturing the array substrate according to claim 1, wherein the step of preparing the first passivation layer on the driving circuit layer includes:
preparing a silicon dioxide layer on the driving circuit layer through a chemical vapor deposition process; and
the silicon dioxide layer covers the driving circuit layer to form the first passivation layer.

18. An array substrate, wherein the array substrate is provided by the method of manufacturing the array substrate of claim 1.

19. A display device, wherein the display device comprises the array substrate according to claim 18.

20. The display device according to claim 19, wherein the array substrate comprises the first passivation layer and the second passivation layer disposed on the driving circuit layer, the first passivation layer comprises silicon oxide, and the second passivation layer includes aluminum oxide.
